(19) United States
(12) Patent Application Publication
(10) Pub. No.: US 2010/0156761 A1
(43) Pub. Date: Jun. 24, 2010

(54) EDGE EMISSIVE DISPLAY DEVICE

(76) Inventors: Janos Veres, Pittsford, NY (US); Roland R. Schindler, II, Pittsford, NY (US)

Correspondence Address: EASTMAN KODAK COMPANY;PATENT LEGAL STAFF, 343 STATE STREET, ROCHESTER, NY, 14650-2201, US

(21) Appl. No.: 12/403,595

(22) Filed: Mar. 13, 2009

Related U.S. Application Data
(60) Provisional application No. 61/139,134, filed on Dec. 19, 2008.

(51) Int. Cl. G09G 3/30

(52) U.S. Cl. 345/76

(57) ABSTRACT

A display device includes a plurality of Y display slices, each display slice having electronic structures, which include a one-dimensional array of X adjacent pixels that emit light from a face edge of the display slice in response to electrical power. The display slices are assembled in a layered arrangement to form an emissive face. Also included are control electrodes, power electrodes, data electrodes, and a connection structure for each display slice. Each connection structure connects at least (a) each of a plurality of groups of the corresponding display slice's pixels to a separate one of the control electrodes, (b) one or more of the power electrodes to at least one of the corresponding display slice's electronic structures, and (c) one or more of the data electrodes to at least one of the corresponding display slice's electronic structures.

### CROSS-REFERENCE TO RELATED APPLICATION

This application claims the benefit of U.S. Provisional Application Ser. No. 61/139,134 filed Dec. 19, 2008, the entire disclosure of which is hereby incorporated herein by reference.

### FIELD OF THE INVENTION

The present invention relates to display devices.

### BACKGROUND

Display devices have been increasing in size and improving in quality. Large display panels are dominated by liquid crystal and plasma displays which are manufactured with a well-established infrastructure based on photolithographic patterning. Recently, there has been growing interest in organic light emissive displays (OLED) with the potential of further improving image quality and reducing power consumption. The manufacture of increasingly large display panels requires careful control of process conditions for image uniformity and yield. This is particularly true for current driven OLED displays where the uniformity of the drive electronics and emissive layers has a severe impact on the display quality. Drive electronics are typically provided by amorphous Silicon (a-Si) or polycrystalline Silicon (p-Si) backplanes. Amorphous Si is excellent in uniformity, but suffers in operational stability, while p-Si is difficult to manufacture uniformly enough on large areas.

Uniform brightness and color of pixels in large displays is also a challenge. This requires good control over the formation of individual light modulating pixels during their manufacture. Possibilities exist to adjust the relative brightness of pixels post manufacture. However, a suitable drive electronics scheme is required that is capable of such post-manufacture adjustments, such as a scheme that is able to continually monitor and tune the performance of each pixel. Integrating such functionality into backplane electronics is a challenge since it requires several additional transistors per pixel. As the size of displays increases, the performance requirements for these transistors is more and more demanding as they need to drive more current.

There is also a need to provide improved functionalities in modern displays. Displays increasingly incorporate interactive functionalities such as touch sensing. These typically rely on a number of conductive, semitransparent patterns in front of the display pixels, thereby reducing the brightness and viewing quality of the display.

There is also a need for displays that can be manufactured in a simplified manner with improved yield and lower cost. In particular, there is a need to provide displays that are able to incorporate the aforementioned quality and functionality requirements while being produced with a scalable and high yield method.

### SUMMARY

The above-described problems are addressed and a technical solution is achieved in the art by various embodiments of the present invention. For example, some embodiments of the present invention pertain to a display device that includes a plurality of Y display slices, each display slice having electronic structures. The electronic structures include a one-dimensional array of X adjacent pixels that emit light from a face edge of the display slice in response to electrical power. The display slices are assembled in a layered arrangement to form an emissive face. Also included are control electrodes, power electrodes, data electrodes, and a connection structure on or in each display slice. Each connection structure connects at least (a) each of a plurality of groups of the corresponding display slice's pixels to a separate one of the control electrodes, (b) one or more of the power electrodes to at least one of the corresponding display slice's electronic structures, and (c) one or more of the data electrodes to at least one of the corresponding display slice's electronic structures.

In some embodiments, the electronic structures in each display slice include a first electronic structure having a first input connected to one of the power electrodes, a second input connected to one of the data electrodes, and a plurality of outputs, each output connected to a different pixel in one of the groups of pixels in the respective display slice. Such an electronic structure can be an integrated circuit.

In some embodiments, each output of the first electronic structure is connected to positionally-corresponding pixels in at least two of the groups of pixels in the respective display slice, and wherein no two outputs of the first electronic structure are connected to a same pixel in any of the groups of pixels. in other embodiments, each output of each first electronic structure is connected to positionally-corresponding pixels in all of the groups of pixels in the respective display slice, and wherein no two outputs of the first electronic structure are connected to a same pixel in any of the groups of pixels.

In some embodiments, each display slice includes a memory circuit connected at least to one of the respective display slice's pixels. In some of these embodiments, each memory circuit includes two pixel-selection transistors, and each memory circuit is connected via the respective pixel-selection transistors to one of the data electrodes. In some of these embodiments, each memory circuit includes a first pixel-selection transistor and a second pixel-selection transistor, and the plurality of control electrodes include a plurality of group-select electrodes and a plurality of column-select electrodes. The first pixel-selection transistors in the memory circuits for one of the groups of pixels in a display slice are controlled by a same group-select electrode, and the second pixel-selection transistors in the memory circuits for the one of the groups of pixels are controlled by different column-select electrodes. In such cases, the display device can include X columns of pixels in the emissive face, and timing circuitry connected to the plurality of group-select electrodes, the plurality of column-select electrodes, and the data electrodes and configured to cause the X columns of pixels to refresh data in their memory circuits in sequence at a frequency greater than 20 Hz.

In some embodiments, each memory circuit comprises a pixel-selection transistor, each memory circuit is connected via the respective pixel-selection transistor to one of the data electrodes, and each display slice includes a first electronic structure having a first input connected to one of the power electrodes, a second input connected to one of the data electrodes, and a plurality of outputs, each output connected to one of the pixel-selection transistors in one of the groups of pixels in the respective display slice.

In some embodiments, each display slice comprises a plurality of control electrodes connected to control electrodes in an adjacent display slice. Connections between control electrodes through all of the display slices form or substantially form a line perpendicular or substantially perpendicular to a plane of the display slice.

In some embodiments, at least one of the electronic structures includes sensing capabilities that detect the proximity of an object.

In some embodiments, a display device includes circuitry on or in each display slice, the circuitry including a plurality of electronic structures, a plurality of power electrodes, a plurality of data electrodes, a pixel selection electrode, and a connection structure, the connection structure connecting the circuitry to the pixels on the respective display slice. In these cases, the circuitry for each display slice can be behind the respective one-dimensional edge-emissive array with respect to the emissive face.

In some embodiments, each of the display slices is formed of a flexible material capable of being formed into a roll. In this regard, in some embodiments, display device components include a plurality of display slices formed side-by-side as a roll of flexible material; a one-dimensional edge-emissive array of adjacent pixels formed with each display slice; a plurality of control electrodes formed with each display slice; a plurality of power electrodes formed with each display slice; a plurality of data electrodes formed with each display slice; and a connection structure formed with each display slice. Each connection structure connects at least (a) each of a plurality of groups of the corresponding display slice's pixels to a separate one of the control electrodes, (b) one or more of the power electrodes to at least one of the corresponding display slice's electronic structures, and (c) one or more of the data electrodes to at least one of the corresponding display slice's electronic structures.

In addition to the embodiments described above, further embodiments will become apparent by reference to the drawings and by study of the following detailed description.

### BRIEF DESCRIPTION OF THE DRAWINGS

The present invention will be more readily understood from the detailed description of exemplary embodiments presented below considered in conjunction with the attached drawings, of which:

FIG. 1 illustrates an emissive face of a two-dimensional display having Y display slices attached to each other in a layered arrangement, according to an embodiment of the present invention;

FIG. 2 illustrates a perspective view of the display in FIG. 1, according to an embodiment of the present invention;

FIG. 3 illustrates a display device with pixel groups and few inter-display-slice interconnects, according to an embodiment of the present invention;

FIG. 4 illustrates a displayed image frame sequence caused by driving the display device of FIG. 1, according to an embodiment of the present invention;

FIG. 5 illustrates a display device where individual pixels have associated memory circuits, according to an embodiment of the present invention;

FIG. 6 illustrates a layout for the device of FIG. 5, according to an embodiment of the present invention;

FIG. 7 illustrates a displayed image frame refresh sequence caused by driving the display device represented in FIGS. 5 and 6, according to an embodiment of the present invention;

FIG. 8 illustrates a display device where pixel columns are individually addressable and individual pixels have associated memory circuits, according to an embodiment of the present invention;

FIG. 9 illustrates a displayed image refresh sequence caused by driving the display device represented in FIG. 8, according to an embodiment of the present invention; and

FIG. 10 illustrates a roll-to-roll manufacturing process, according to an embodiment of the present invention, for a display device according at least to the embodiments of FIGS. 3, 5, and 8.

It is to be understood that the attached drawings are for purposes of illustrating the concepts of the invention and may not be to scale.

### DETAILED DESCRIPTION

Various embodiments of the present invention provide a display device having a two dimensional emissive display face that is formed from layers of display slices having pixels that emit light from edges of the display slices. Such designs allows all or most of the control circuitry associated with pixels on a display slice to be located behind the pixels with respect to the emissive face, thereby reducing a thickness of the display slices. A reduced thickness of display slices allows more display slices to be incorporated into a display and, consequently, allows higher resolution, functionality, or both. Further, the control circuitry designs of various embodiments of the present invention can be incorporated onto or into flexible substrates, which enables roll-to-roll or web manufacture of displays on an arbitrarily large scale. The local drive electronics associated with embodiments of the present invention enable relatively large, and easy to manufacture, transistors and other features, thereby improving manufacturing yield.

It should be noted that, unless otherwise explicitly noted or required by context, the word “or” is used in this disclosure in a non-exclusive sense.

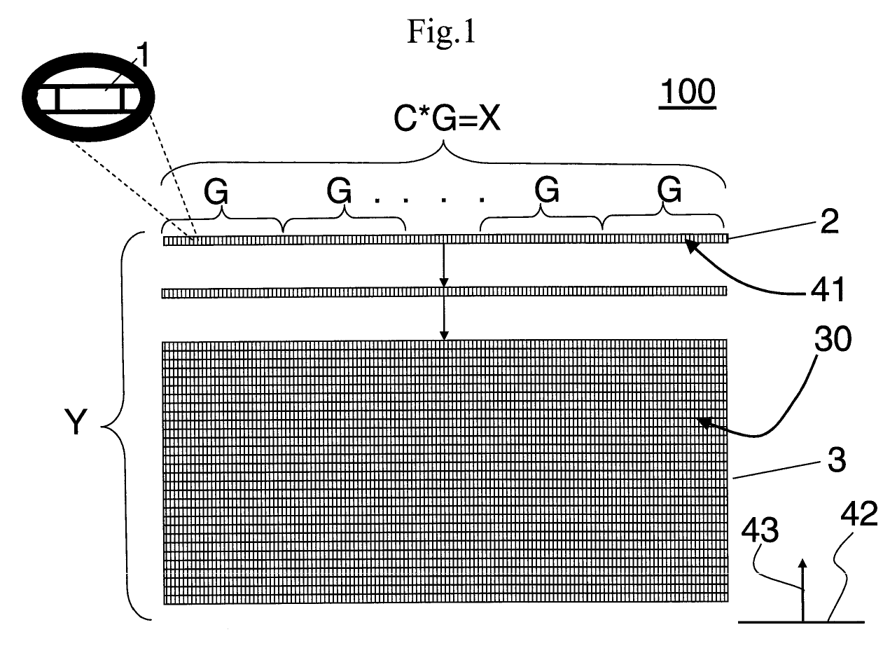

FIG. 1 illustrates an emissive face of a two-dimensional display 100 having a plurality Y of display slices 2 assembled in a layered arrangement, such as a stack, according to an embodiment of the present invention. In this embodiment, each display slice 2 includes a one-dimensional array of X individual pixels 1 that emit light from a face edge 41 of the corresponding display slice in response to electrical power. The layering of the display slices 2 causes a two-dimensional array of pixels 3, collectively forming an emissive face 30 of a display device.

In order to drive a plurality of display slices 2 efficiently, the pixels 1 on each slice are joined into C groups, in this case, each group including G neighboring pixels. In FIG. 1, C*G=X, where C, G, and X are integers. In some embodiments, the number of pixels G in a group is between 8 and 256. However, some implementations will find the number of pixels G to preferably be between 12 and 128, or 15 and 64. It should be noted, however, that the invention is not limited to any particular number of pixels in a group of pixels.

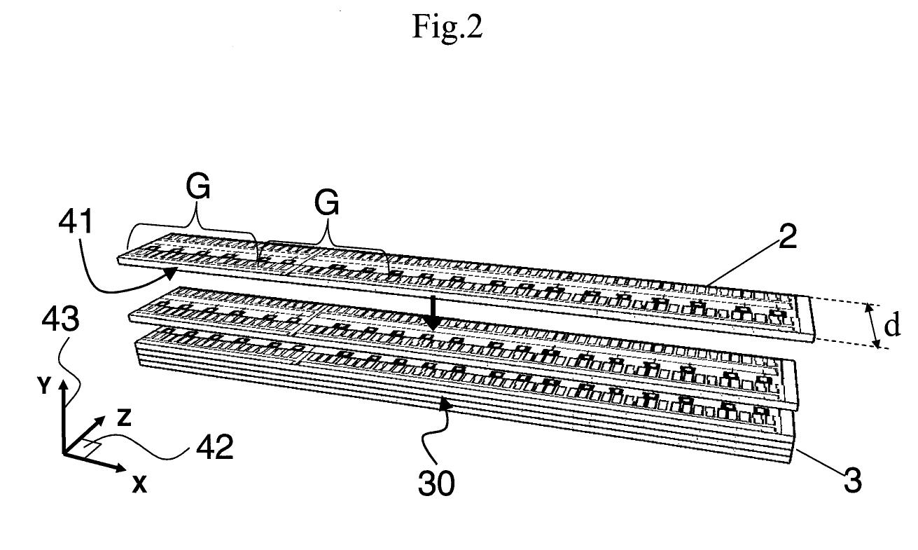

FIG. 2 illustrates a perspective view of display 100 showing the width of display slices 2 extending into the depth d of the display in dimension “Z”. The width d of the display slices 2 represents the depth (or thickness) of the final display device. The face edge 41 of each display slice 2 forms one layer of the emissive face 30.

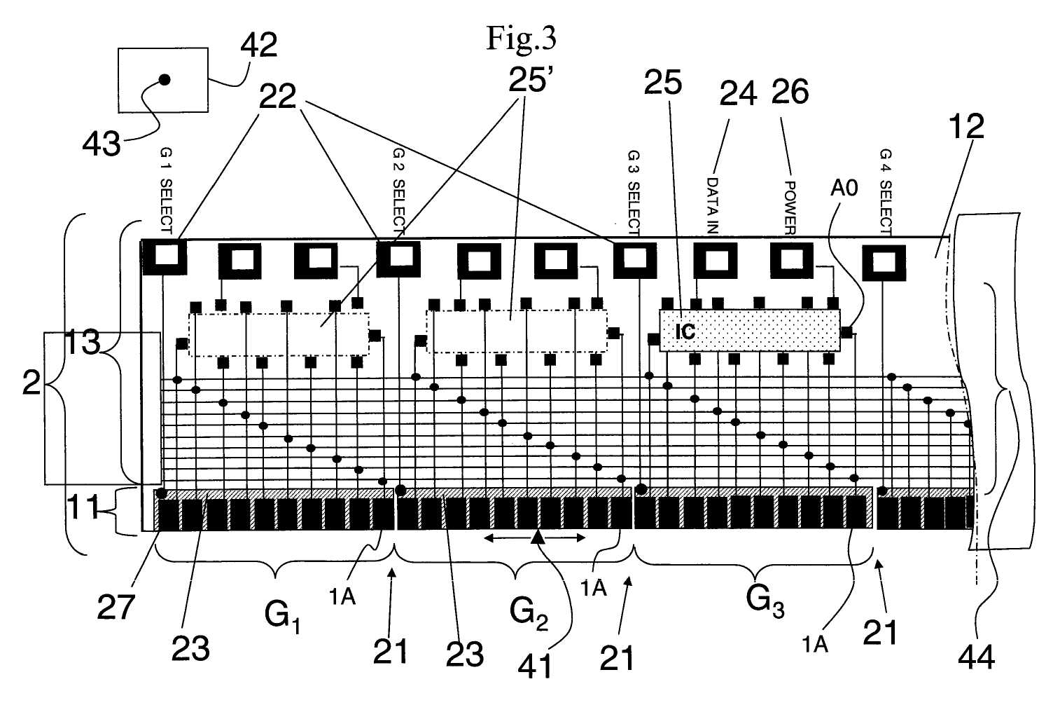

The embodiment shown in FIG. 3 depicts a top surface of a display slice 2. The display slice 2 includes electronic structures, such as the emissive pixels 27 in the one-dimensional array 11, and circuitry 13, both of which are formed on substrate 12. The circuitry 13 also includes electronic structures, such as control electrodes 22, power electrodes 26, data electrodes 24, one or more IC chips 25, and a connection structure 44 connecting various electrodes 10 either the IC chip(s) 25 or the pixels 27. The circuitry 13 can be considered control circuitry or a portion thereof.

The pixels 27 are grouped by the connection structure 44 into groups G1, G2, G3 and so on. For simplicity, each group is shown to include ten pixels in FIG. 3. In this embodiment, pixels in each group are connected to a common anode or cathode 23 for the emissive elements, the common anode or cathode being connected to a same control electrode. In other words, pixels within one group share (i.e., are connected to a same) control electrode, which selects which group is being addressed. Each of these control electrodes is called a GROUP SELECT and is connected to a contact pad (also part of the electrode) at the rear of the corresponding display slice 2. Electrodes 22 of GROUP SELECT electrodes G1 SELECT, G2 SELECT, and so on, are connected to the same electrodes on adjacent slices below and above the display slice 2. As a result, G1 SELECT selects the first pixel group G1 in all slices of the display. In certain embodiments of the present invention, the connections between control electrodes for a particular group of pixels forms or substantially forms a line 43 that is perpendicular or substantially perpendicular to a plane 42 in which the display slice 2 resides.

The IC chip 25 has a first input connected to the power electrode 26, and a second input connected to the data-input electrode 24. The data, i.e., brightness information, for each pixel is provided first to the IC chip 25 via the data-input electrode. When data for all pixels in a group have been received by the IC chip 25, such data is supplied by the IC chip 25 via ouputs, each connected to a different pixel in a group of pixels in FIG. 3. Consequently, the IC chip 25 and timing circuitry (not shown) connected to the data-input electrode 24, acts as a column driver circuit that can simultaneously address a group of columns.

To elaborate, in FIG. 3, the IC chip 25 has ten data output connections or pins (represented by black squares (other than for data input 24 and power 26) around the outside of IC chip 25). Connection structure 44 connects the output connections to pixels 1 on the display slice 2. For example, in the embodiment illustrated in FIG. 3, a first output connection A0 is connected to a first pixel 1A in each group within the display slice 2. IC chip 25 can drive current to the pixels and control their brightness, for example, by either pulse width- or amplitude modulation. Image data can be provided to the IC chip 25 by serial signal via electrode 24. One or more serial signals may be used depending on bandwidth requirements. If the data-input electrode 24 is linked to respective connections on adjacent display slices 2, it may be necessary to have an identification address for each IC chip on each slice 2 of the display 100. Alternatively, additional addressing electrodes may be provided to address a particular IC on a display slice. There are further electrodes 26 on the display slice 2 to provide power to the circuitry 13. Several power connections may be used depending on the needs of the digital/analog circuitry in IC chip 15.

In the embodiment shown in FIG. 3, the display slice 2 provides redundant mounting positions 25′ for IC chips at the interval of one or more pixel groups. This is to provide space for optional mounting of K chips, and to enable the manufacture of a continuous web of display slices, which can be cut at any point between the pixel groups, for example, at position 21. The redundant mounting positions 25′ also are beneficial to ensure circuit symmetry ensuring equal length for each data line and identical stray capacitance. In some applications, it can be preferred that a display slice 2 uses less than 4 IC chips to drive the pixels of the plurality of groups on a slice 2. In still other applications, most preferably one IC chip can be used to drive the plurality of groups on a display slice 2.

Although the description herein often refers to an IC chip, any form of circuit logic may be used, and such logic may be formed as part of the display slice, instead of being a separately added component. In this regard, the IC chips may also be chiplets, i.e., small silicon crystals without a package. The chips or chiplets may be flip chips mounted or connected at the time of depositing and patterning the interconnect lines on substrate 12.

In instances where an IC chip 25 is provided on a one-to-one basis with pixel groups, each output of an IC chip is connected to a different pixel in the corresponding group of pixels. In instances where an IC chip 25 is provided on a one-chip-to-many basis with pixel groups, each output of a chip is connected to positionally-corresponding pixels in at least two of the groups of pixels in the respective display slice, and no two outputs of the chip are connected to a same pixel in any of the groups of pixels. In instances where a single chip 25 is provided for each display slice 2, each output of the chip can be connected to positionally-corresponding pixels in all of the groups of pixels in the respective display slice, with no two outputs of the chip are connected to a same pixel in any of the groups of pixels.

In the arrangement of FIG. 3, IC chip 25 plus redundant mounting positions 25′ are positioned at a frequency of one pixel group. This makes it possible to cut the display slice 2 in between every pixel group. It may be envisaged that space for IC 25 is provided at the frequency of every two or three pixel groups. This yields more space for connections 22, 24, and 26 at the rear of the slice. In turn, such a display slice may be cut at intervals corresponding to the frequency of chip spacing—i.e. at the interval of every two or more pixel groups. It is envisaged that in a roll-to-roll process the pixel groups are tested before cutting. A length of defect free display slice equivalent of the width of the display can be sought and can be identified through testing of the pixel groups. Nonworking pixel groups are cut and discarded. Cutting may be performed in the middle of the area between two display groups or partially on a non-working group to provide space for cutting. It may also be possible to provide greater space for cutting at intervals equivalent of the display width. Note that the display slices may also be arranged vertically—i.e. equivalent of rotating FIG. 1 by 90 degrees.

Electrodes 22, 24, 26 in FIG. 3 can be connected to adjacent slices above and below the display slice 2. Electrodes 22, 24 and 26 may be formed with a via hole to facilitate connections. These vias may have the shape of sprocket holes used in the perforation of photographic film. Electrical connection between adjacent layers can be made, for example, by anistoropic conductive paste or film in certain embodiments. This anisotropic conductor can also act as an adhesive between layers.

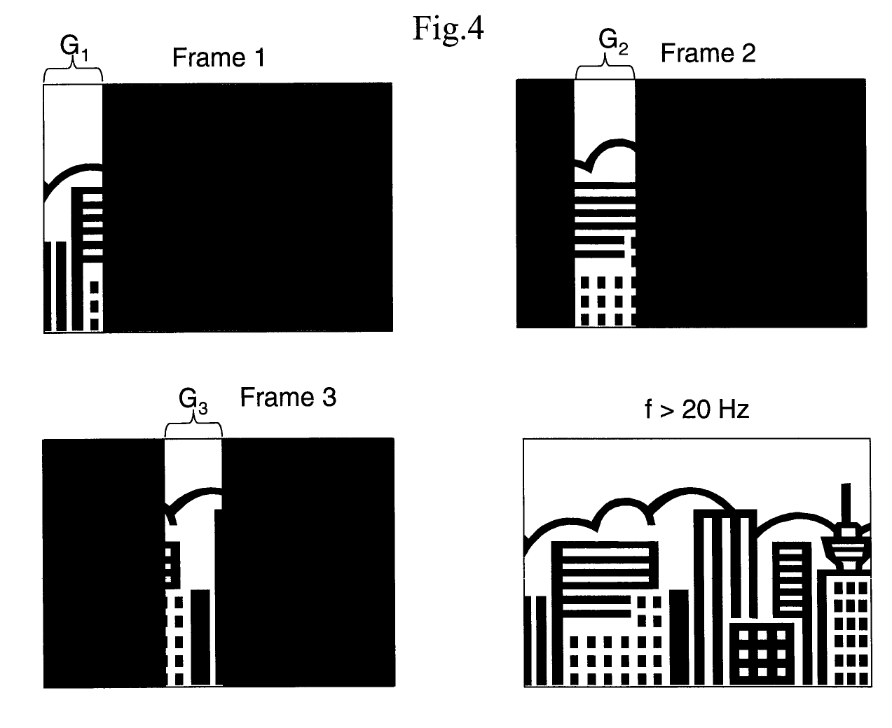

FIG. 4 illustrates the operational sequence of a display according to the embodiment of FIG. 3. In the first frame cycle of the display, external timing circuitry (not shown) selects the first group of pixels in each display slice 2 using electrode G1 SELECT of FIG. 3. At the same time, the column driver IC chips 25 of FIG. 3 provide data signals to the first pixel group G₁ in each slice. As a result the display pixels turn on Frame1 equivalent to the plurality of the first pixel groups on each slice, resulting in the presentation of image information that is illustrated in FIG. 4, frame1. In the second frame cycle, G2 SELECT turns on all of the second pixel groups. The column driver IC chips 25 provide data signals to the pixels in group G₂ in each slice, resulting in the presentation of image information that is illustrated in FIG. 4, frame2. This sequence continues until the last pixel group is reached. After this the frame cycle repeats. When the frame cycle is repeated at a frequency greater than 20 Hz, the viewer sees the full image on the display. The frame cycle repeat frequency can be between 10 Hz and 1000 Hz, but some applications may find a frequency between 20 Hz and 500 Hz or between 25 Hz and 300 Hz preferable. It should be noted that the display of this embodiment operates as a “quasi-passive matrix” (QPM) display in which groups of pixels light up at a time. Conventional passive matrix (PM) displays exhibit one line at a time. As a result, PM displays cannot be easily scaled without the loss of brightness. Large numbers of lines require very high frequencies to operate the display and therefore consume much power and demand excessively high drive currents. The grouping of the pixels in each slice results in a quasi passive matrix operation which is equivalent to a passive matrix display with C columns, where is the number of pixel groups in each slice. Passive matrix displays are difficult to fabricate with more than 256 columns. The current invention enables high definition displays to implement a quasi passive matrix drive via the use of pixel groups.

Table 1 illustrates some possible combinations of pixel groups for high definition displays according to the embodiment of FIG. 3.

TABLE 1

| | X | Y | G | C | N | P |
|---|---|---|---|---|---|---|
| HD1 | 1920 | 1080 *RGB | 8 | 240 | 11-22 | 243-253 |
| HD2 | 1920 | 1080 *RGB | 15 | 128 | 18-29 | 131-141 |
| HD3 | 1920 | 1080 *RGB | 30 | 64 | 33-44 | 67-77 |
| HD4 | 1920 | 1080 *RGB | 40 | 48 | 43-54 | 51-61 |
| 2HD1 | 3840 | 2160 *RGB | 15 | 256 | 18-30 | 259-271 |
| 2HD2 | 3840 | 2160 *RGB | 30 | 128 | 33-45 | 131-142 |
| 2HD3 | 3840 | 2160 *RGB | 40 | 96 | 43-55 | 51-62 |

HD1, HD2, HD3 and HD4 are displays with the current “full HD” specification of 1920*1080 pixels. 2HD1, 2HD2 and 2HD3 are displays with double of the resolution of the full HD specification. X and Y is the number of horizontal and vertical pixels respectively, as described in FIG. 1. In this regard, X can be considered the number of columns in the display and Y can be considered the number of rows in the display. Column Y in Table 1 indicates that the number of physical pixels is three times more to allow for red, green and blue pixels (RGB). In the current invention this is provided by alternating red, green and blue display slices. In Table 1, G is the number of pixels grouped per pixel group on each display slice and C is the number of groups in one slice. For ease of understanding, Table 1 assumes that all pixel groups have the same number G of pixels. It will be appreciated that in certain embodiments this may be so, while in other embodiments, different pixel groups on the same slice may have different numbers of pixels.

In the example of Table 1, X=G*C. N gives an example for the range of input connections required for each chip. P is the approximate range for interconnects required between adjacent display slices. The lower limit for N can be estimated by the requirement for the IC to connect to G pixel data lines and have at least two more power connections and at least one serial data connection. Thus, the lower limit for N is G+3. The upper limit for N can be estimated from the need to have connections to G pixel data lines and assuming an external addressing scheme to select one of the display slices to receive data. Typically 11 or 12 bits will be required to address 1080*3 or 2160*3 display slices. Thus, the upper limit for N is estimated to be G+3+11 for HD1 and G+3+12 for HD2. P is the range for the number of pad interconnects in between display slices. The lower limit for P is obtained from the need to have at least C connections to select the display slices, plus two more power and at least one serial data connections. The lower limit for P is, therefore, C+3. The upper limit for P may be estimated from the need to have at least C connections to select the display slices, plus data, power lines and 11 or 12 bits for an external address scheme to select one display slice. Thus, the upper limit for P is C+3+11 for HD and C+3+12 for 2HD. Note that these numbers are for illustration only and as the display size and its pixel group scheme changes, they may be modified accordingly.

HD3 illustrates one example of an attractive drive scheme, employing 1080*3=3240 display slices, each having one IC chip 25. Each of these chips would typically have 33-44 connections to the display slice. The display slices in turn have between 67-77 connections to each neighboring display slice. Note that this is also the total number of connections to the entire display, which is very small compared to existing display panels. This laminated display does not require integration of further row or column drivers on the panel. The entire panel operates as a quasi-passive matrix display having 64 effective columns.

Table 1 also illustrates that the drive scheme is scalable for higher resolution panels. 2HD2 is a display that can be realized with the same IC chips as HD3. The number of connections on each chip is 33-45 and the number of panel connections is approximately between 131-142. The entire panel operates as a quasi-passive matrix display having 128 effective columns.

The pixel group scheme allows building HD3 and 2HD2 with a surprisingly low number of panel connections. The architecture is particularly advantageous for high resolution panels, since the system is easily scalable without necessarily requiring more chips.

TABLE 1

| | X | Y | G | C | N | P |
|---|---|---|---|---|---|---|
| HD1 | 1920 | 1080 *RGB | 8 | 240 | 11-22 | 243-253 |
| HD2 | 1920 | 1080 *RGB | 15 | 128 | 18-29 | 131-141 |
| HD3 | 1920 | 1080 *RGB | 30 | 64 | 33-44 | 67-77 |
| HD4 | 1920 | 1080 *RGB | 40 | 48 | 43-54 | 51-61 |
| 2HD1 | 3840 | 2160 *RGB | 15 | 256 | 18-30 | 259-271 |
| 2HD2 | 3840 | 2160 *RGB | 30 | 128 | 33-45 | 131-142 |
| 2HD3 | 3840 | 2160 *RGB | 40 | 96 | 43-55 | 51-62 |

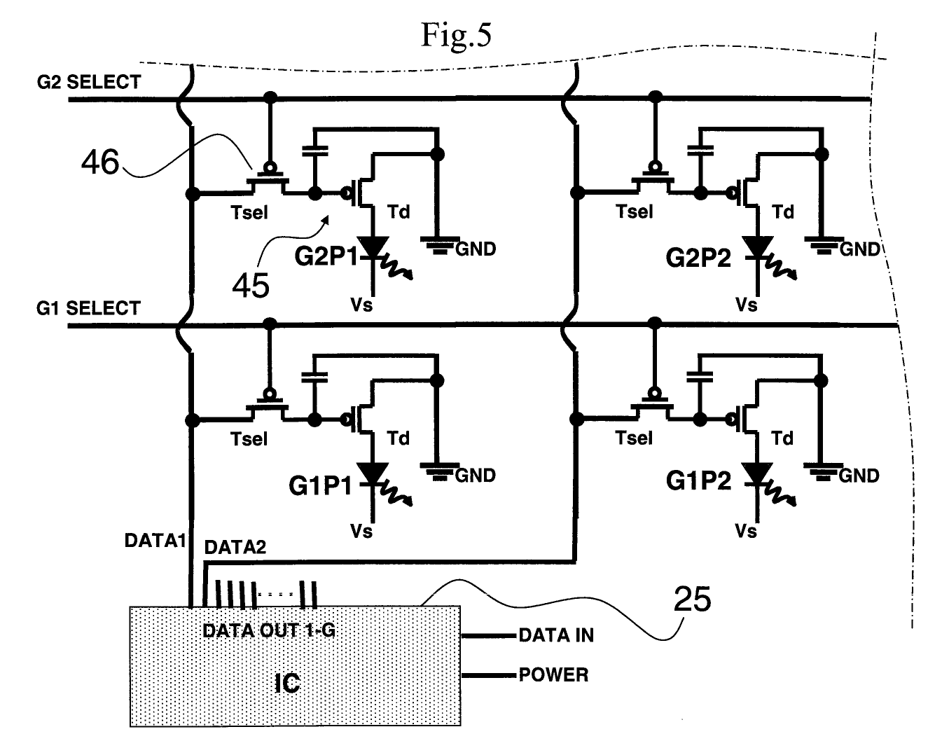

FIG. 5 illustrates another embodiment of the invention, where IC chips 25 are still addressing one pixel group at a time on each display slice, but, there is provided a memory circuit 45, in this case a thin film transistor circuit, for each pixel to store pixel information. In this regard, one of ordinary skill in the art will appreciate that thin film circuits can be used at least in part as control circuitry in various embodiments of the present invention, such as, without limitation, those shown in FIGS. 5, 6, and 8. Thin film circuitry can include a-Si, p-Si, organic TFT, or the like, where semiconductor material is grown or coated on a substrate.

In FIG. 5, as with the embodiment of FIG. 3, IC chip 25 has a first input connected to a power electrode, a second input connected to a data electrode, and a plurality of G data outputs, each connected to positionally-corresponding pixels in at least two of the groups of pixels in the respective display slice. No two outputs of the IC chip 25 are connected to a same pixel in any of the groups of pixels. Such outputs, consequently, forward pixel data to each pixel within one group.

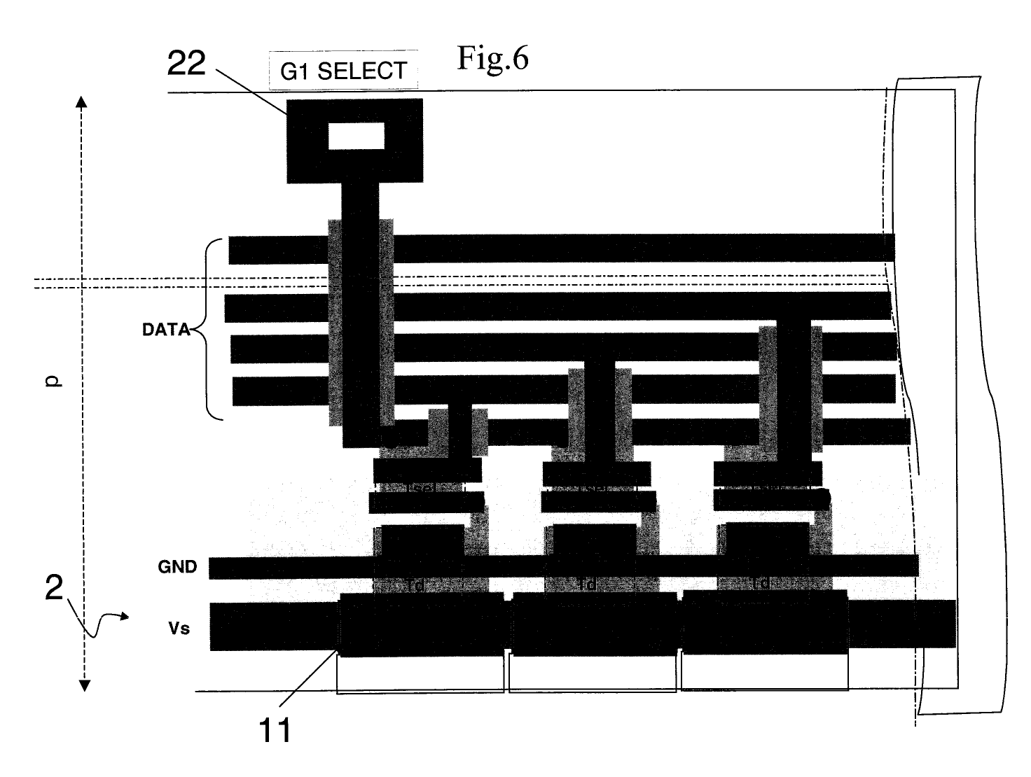

Group select signals G1 SELECT, G2 SELECT, etc., select which pixel group is receiving data. For example, once G1 SELECT is active (i.e., on), pixel-selection transistors Tsel 46 are in on state for all pixels in group G1, and the data from IC chip 25 is stored in respective pixel capacitors in memory circuits 45 for the pixels in group G1. Consequently, all pixels (GIP1, G1P2 and so on) in group G1 are simultaneously receiving and storing the data. An advantage of this arrangement is that the display slices form an effective active matrix (AM) display. A top view showing a local layout of pixels 1 and memory circuits 45 according to FIG. 5 is shown in FIG. 6, according to an embodiment of the present invention. As is shown in FIG. 6, this local layout can be provided using width d of slice 2.

Although the embodiment of FIG. 5 shows a one-to-one correspondence between memory circuits 45 and pixels, one skilled in the art will appreciate that not every pixel 1 needs its own memory circuit 45 and that a single memory circuit 45 can be designed for multiple pixels.

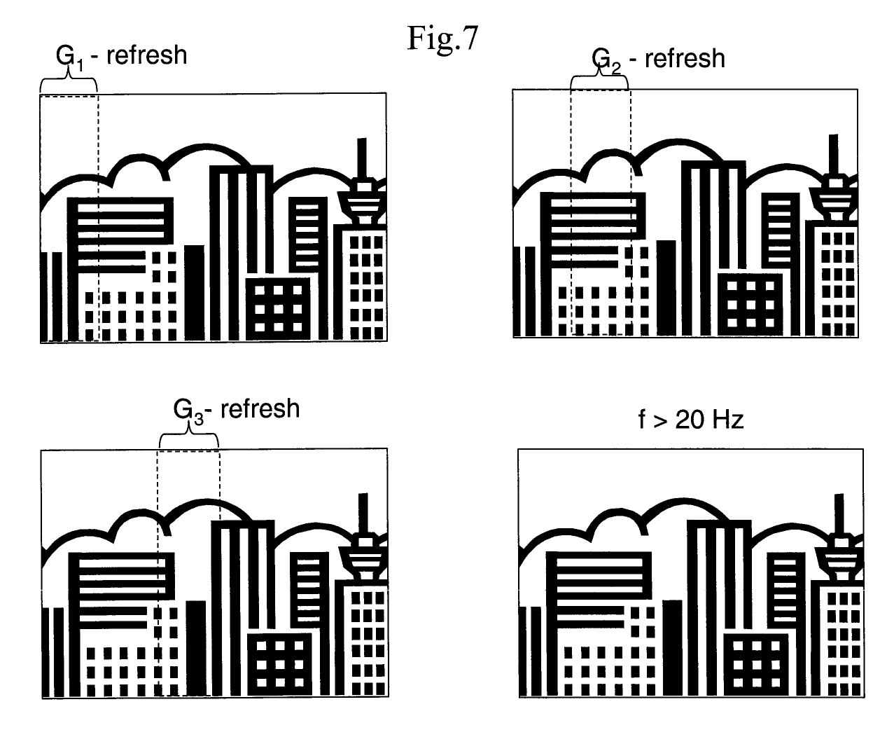

FIG. 7 illustrates an operational sequence, according to the embodiment of FIG. 5. At any time, IC chips 25 on each display slice address one pixel group to refresh their data. Because of the memory circuits 45, however, pixels in groups not being refreshed still emit light. As a first step of the frame refresh cycle, groups G1 on all slices are refreshed. In the second step of the frame refresh cycle, groups G2 are refreshed. This process is repeated for groups G3, G4, etc., until the last groups are refreshed in the display. At frequencies greater than 20 Hz of the frame refresh cycle the viewer no longer can distinguish which groups is being refreshed. Thus the entire image is visible to the viewer without artifacts.

It will be appreciated from this that in certain embodiments, for example, where image information remains static for a period of time, the memory circuits 45 can maintain the presentation of the static image without the necessity of a refresh. It will also be appreciated that a frame refresh cycle lower than 20 Hz can be used where the presence of artifacts is acceptable.

The pixels can be grouped in a similar fashion as shown in Table 1. The number of GROUP SELECT connections G, corresponding chip connections N and panel connections P is approximately the same in the embodiment of FIG. 5. A difference, however, is the additional memory circuits to store pixel information.

Pixel circuitry, according to embodiments like FIG. 5, may be significantly improved compared to conventional pixel circuitry in active matrix displays. First, due to the grouping scheme, the frame refresh cycle in this scheme contains only C steps, i.e., the equivalent of the number of pixel groups per display slice. As a result, the effective refresh frequency is reduced by a factor of G. This in turn makes it possible to use slower transistors with lower mobility and accepting greater stray capacitances. A factor of G=30, for example, means that the transistors may be larger, for example containing larger channel lengths while still performing adequately. Transistor features at design rules of 5 microns are easier to pattern and manufacture. In addition, the increased space on the surface of the display slice allows space for larger TFT dimensions to allow for greater drive currents. Given the increased space, by a factor of 100 or more (compared to the pixel face) and the reduced refresh rate by a factor of 30 or more (compared to conventional AM displays) it is not unreasonable to anticipate that organic transistors of 0.1 cm²V⁻¹s⁻¹ mobility, patterned at 10-20 micron resolution may adequately perform current driving functions.

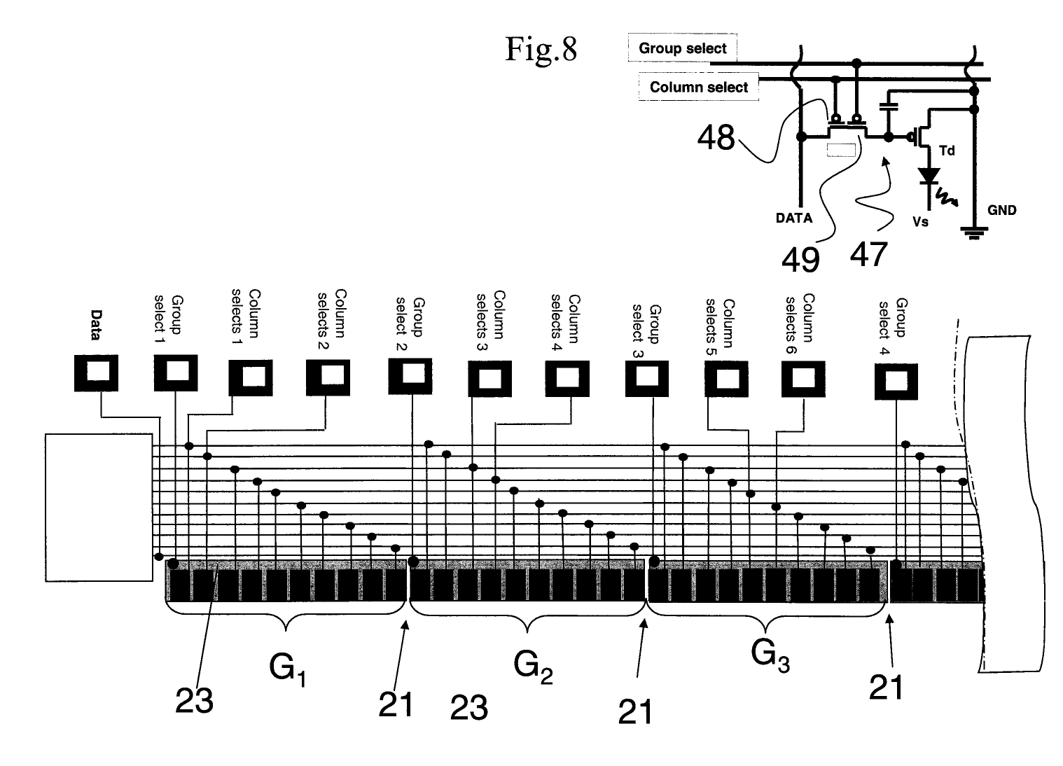

FIG. 8 illustrates another embodiment of the present invention where each pixel has an associated memory circuit 47. In this embodiment, however, each memory circuit 47 includes a first pixel selection transistor 49 and a second pixel selection transistor 48 in series (this might also be viewed as a single transistor with two gates performing an “AND” function). All of the first pixel-selection transistors 49 in a group of pixels are connected to and controlled by a same group-select control electrode. However, all of the second pixel-selection transistors 48 in a group of pixels are connected to and controlled by a different column-select control electrode. Consequently, a GROUP SELECT signal from a group-select control electrode activates a particular group of pixels, and a COLUMN SELECT signal from a column-select control electrode activates a particular pixel with the activated group. Therefore, these two signals uniquely identify which pixel is being addressed in a display slice.

When a pixel is addressed by GROUP SELECT and COLUMN SELECT, corresponding pixel data is stored in the addressed pixel's capacitor in the corresponding memory circuit 47. Although other variations exist within the scope of the invention, the data originates in FIG. 8 from a single DATA connection leading to all pixels in the display slice. GROUP SELECT and COLUMN SELECT lines are connected to the rear of the display slice and are in turn connected to corresponding signal pads on adjacent display slices above and below, as with FIGS. 3 and 5. Thus, by driving global GROUP SELECT and COLUMN SELECT signals, the same pixel position can be addressed across each display slice. At the same time the number of connections P between the laminated display slices is significantly smaller than the number of pixels in each slice, as shown in Table 2. In this embodiment P includes GROUPS SELECT connectors and COLUMN SELECT connectors, plus at least two power lines. Thus approximately P=G+C+2. Table 2 illustrates that a realistic number of connectors may be formed between display slices and their adjacent neighbors above and below.

TABLE 2

| | X | Y | G | C | N | P |
|---|---|---|---|---|---|---|
| HD1 | 1920 | 1080 *RGB | 8 | 240 | NA | 250 |
| HD2 | 1920 | 1080 *RGB | 15 | 128 | NA | 145 |
| HD3 | 1920 | 1080 *RGB | 30 | 64 | NA | 96 |
| HD4 | 1920 | 1080 *RGB | 40 | 48 | NA | 90 |
| 2HD1 | 3840 | 2160 *RGB | 15 | 256 | NA | 273 |
| 2HD2 | 3840 | 2160 *RGB | 30 | 128 | NA | 160 |
| 2HD3 | 3840 | 2160 *RGB | 40 | 96 | NA | 138 |

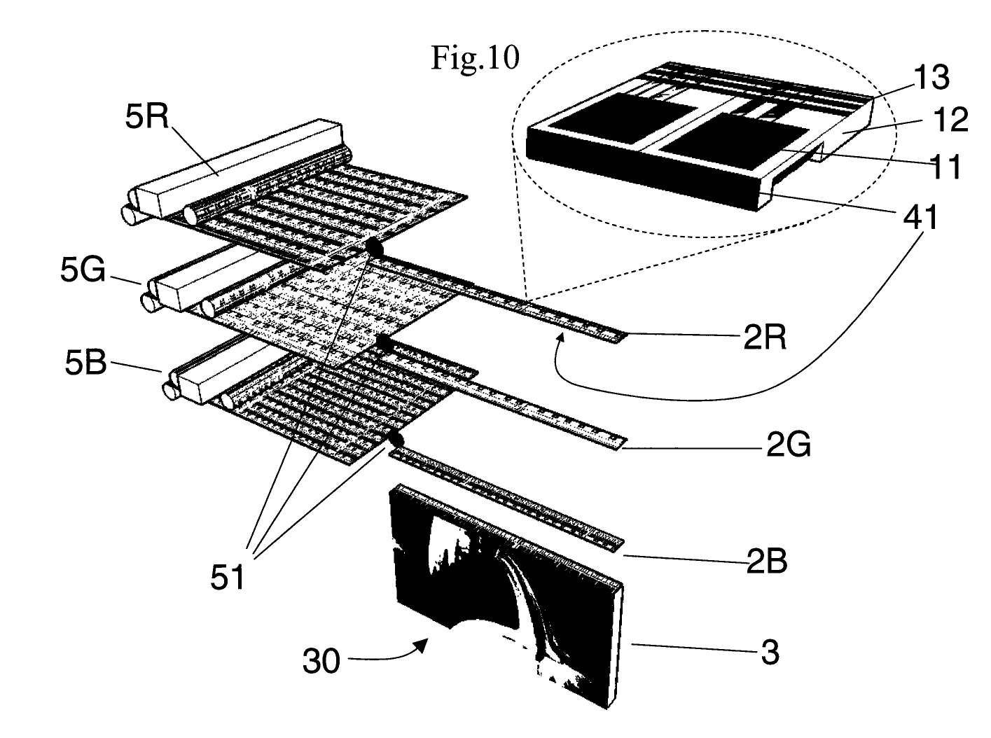

It should be noted that the spacing and order of these SELECT connectors may be different for that shown in FIG. 8. The pixel grouping allows there to be a number of interconnects substantially smaller than the number of pixels X in each slice. This embodiment eliminates the IC chips 25 mounted on each slice and fully relies on the pixel circuits 31. One DATA electrode is provided to each display slice in the embodiment of FIG. 8. That is, DATA electrodes are not interconnected between display slices in the embodiment of FIG. 8. These data electrodes can be provided at the rear of the slices as shown in FIG. 8 to keep circuitry behind the pixels with respect to the face edge of the respective display slice, as will be described in more detail below with respect to FIG. 10.

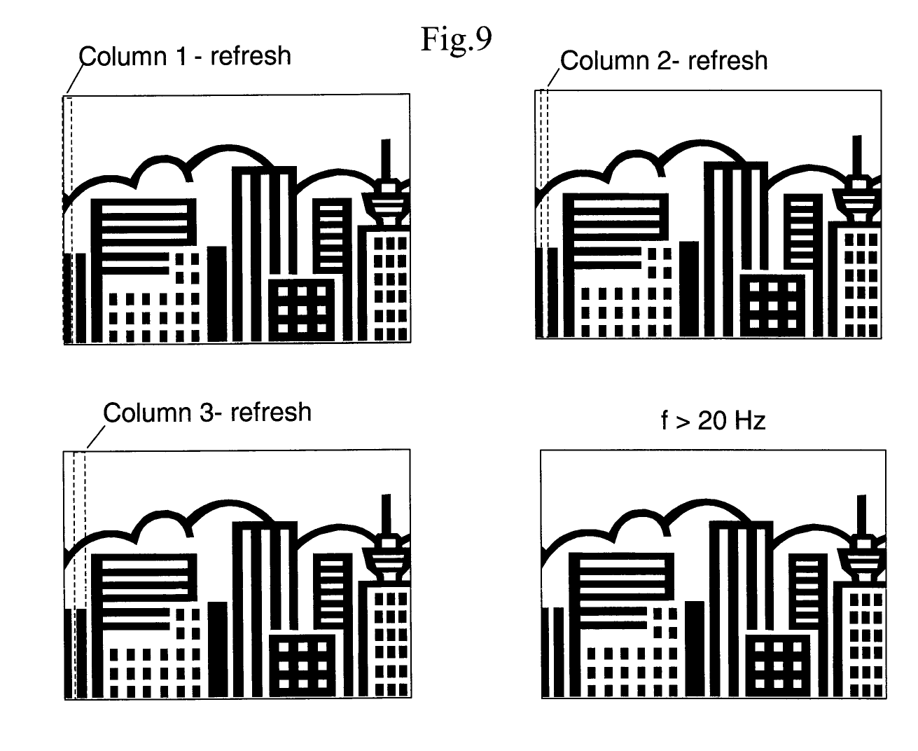

FIG. 9 illustrates an operational sequence generated by a timing circuit, not shown, connected to the group-select and column-select electrodes according to the embodiment of FIG. 8. First, the timing circuit activates the GROUP SELECT 1 electrode, activating the first pixel group G1 on each display slice. Subsequently, the timing circuit activates the COLUMN SELECT 1 electrode, activating the first pixel within that group. This enables a frame refresh cycle for a first pixel column of the entire display. At this time DATA connectors provide the pixel information to each display slice. Subsequently, the timing circuit activates the COLUMN SELECT 2 electrode, activating the second pixel in the first group of each display slice. This is repeated until all of the G columns within the first group of all slices have received their refreshed data. The above sequence is then repeated to address the second pixel group on each display slice, then the third group, etc., until the last group has received their refreshed data.

At low frequencies it appears for the viewer that the information is refreshed pixel-column by pixel-column. At frequencies greater than 20 Hz for the refresh of the entire display, the viewer sees the full image without the refresh operation being noticeable.

### Manufacturing Processes

The drive schemes according to various embodiments of the present invention reduce the number of connections in and between layered display slices 2. The specified pixel arrangements make it possible to form the drive electronics as well as the pixels on the surface of the display slice. This formation can be accomplished in a continuous roll-to-roll process, by forming several display slices simultaneously on a wide web. FIG. 10 illustrates a possible process, in which three separate web lines, or side-by-side groups 5R, 5G, and 5B of display slices 2 are manufacturing or formed as rolls of flexible material. In this case, each side-by-side group 5R, 5G, and 5B include pixels for a different color channel, such as red for group 5R, green for group 5G, and blue for group 5B. The display slices in each group 5R, 5G, and 5B are cut or otherwise separated into display slices 2R, 2G, and 2B respectively. The width d of the slices 2 may be 2 mm to 100 mm, more preferably 4 mm to 50 mm even more preferably 5 mm to 35 mm. These separated display slices 2R, 2G, 2B, and others like them, are joined together, such as by laminating or the use of an anistoropic conductive paste or film, to form the two dimensional array 3 of pixels 1 as previously described. As shown in FIG. 10, separated display slices for different color channels, including 2R, 2G, and 2B, can be joined in a repeating manner: e.g., red, green, blue, red, green, blue, on so on. Also, the separated display slices can be joined in the layered manners previously described, such as by the forming of connections at least between control electrodes in each display slice. And as previously described, for example, such connections can form or substantially form a line perpendicular or substantially perpendicular to a plane of each layered display slice. However, one of ordinary skill in the art will appreciate that any of the inter-slice connection techniques described herein can be used with the techniques shown in FIG. 10.

The inset in FIG. 10 shows two pixels magnified, where 41 is the face edge of emissive pixels 11. Part of the substrate 12 or the substrate itself can form the lightguide transmitting the light from the emissive pixel to the face edge 41 of the pixel. The circuitry 13 is located behind the pixels 11 on the substrate 12, according to some embodiments of the present invention.

Light emitted from a pixel 11 can be coupled to the face edge 41 by a variety of structural and optical solutions. For example, at least three approaches can be used: a) mirror structures to reflect the light towards the front face, b) total internal reflection architectures guiding the light in a lightguide forming part of the substrate 12, or c) dye doped lightguides that absorb and re-emit the light towards the front face. Dyes, phosphors, quantum dots or other colorants may also be used within such waveguide or mirror structures. These absorb the perpendicularly emitted light and re-emit it within a lightguide structure. Light coupling may employ mirrors, total internal reflection, scattering or absorption/re-emission solutions as a combination of the above approaches. The coupling solution may be different for each color. Known edge-emissive structures may be employed in the invention. For example, edge emissive pixels described in U.S. Pat. No. 4,535,341 to Kun et al.; U.S. Pat. No. 5,994,835 to Wilson et al.; and U.S. Pat. No. 7,129,965 to Iwamatsu et al. might be used. The lightguides in substrate 12 can be formed by embossing, printing, photolithography or any other suitable patterning technique. Reflective materials may be sputtered or evaporated metal, or coated, printed nanoparticle metal layers. Scattering materials such as TiO₂ may also be sputtered or solution coated. Dyes, phosphors, or other colorants may be incorporated by evaporation or solution coating, printing.

The pixels 1 of emissive pixel array 11 can be an organic light emitting diode (OLED). Solution coated polymer light emitting diodes (PLED) or evaporated small molecule organic light emitting diodes can be used (SMOLED). Combinations of PLED and SMOLED layers or their blended formulations can also be used.

The current invention is useful for, among other things, the manufacture of large SMOLED panels. SMOLED are currently patterned by shadow mask processes to define red, green, and blue pixels, the process having limitations for the size and resolution of SMOLED panels. The circuitry 13 of the current invention enables the manufacture of high resolution, large laminated OLED panels. Red, green, and blue display slices can be manufactured separately, without the need for accurate registration of shadow masks for the different colors. The manufacture of SMOLED panels is currently inherently limited to panels about 600 mm diameter due to the registration difficulties of fine shadow masks.

Further advantages of the invention are the enabled optical qualities for the laminate edge emissive panel (LEEP). The display slices can comprise a greater surface emissive pixel 11 than the actual face edge 41 of the pixels, resulting in a higher brightness pixel. Furthermore, it becomes possible to operate the SMOLED material at low voltage regime at its ideal power efficiency. Since the OLED may run at low voltage and brightness, the operational life may be extended. Defects in the plane of the pixel will not be visible to the viewer. As defects (dark spots) develop, the external effect is overall reduction of brightness, which may compensated by gradually increasing the drive voltage or keeping the drive current constant. Additional drive electronics in circuitry 13 may be envisaged for this purpose.

While OLED displays are one example display mode of the current invention, it can be envisaged that the display slices may employ inorganic emissive materials such as AC or DC electroluminescent materials. The display may also be built as a laminated array of liquid crystal (LCD), or plasma modules. Optionally the display may comprise a color filter as part of the face edge 41. Indeed, any emissive display mode may be utilized to form one dimensional pixel arrays and form them into two dimensional architectures using the structural and drive schemes according to various embodiments of the invention. Preferably, the emissive materials may be electroluminescent, phosphorescent organic or inorganic materials. The materials may be evaporated or liquid coated from a dispersion or a solution. In some embodiments, the emissive materials are SMOLED, PLED materials, or inorganic nanoparticles.

Any suitable substrate 12 may be used to form laminate arrays, for example, plastic, glass, steel, ceramic, or composite materials. In some embodiments, the substrate 12 is a plastic material such as polyester, polycarbonate, polyethylene-naphthalene (PEN), polystyrene etc.

The circuitry 13 formed on the surface of the display slices also makes it possible to integrate sensing functionalities. By using silicon chips on each display slice as shown in FIG. 3, sufficient level of logic and electronic sensing capability can be provided on each slice. IC chip 25 in FIG. 3, for example, can perform a current measurement function to monitor pixel operation. The same circuit may also be used to measure capacitive coupling between neighboring pixels due to proximity of an object or a finger. It can be seen that the distributed drive electronics enables building further functionality into the display architecture.

It is to be understood that the exemplary embodiments are merely illustrative of the present invention and that many variations of the above-described embodiments can be devised by one skilled in the art without departing from the scope of the invention. It is therefore intended that all such variations be included within the scope of the following claims and their equivalents.

### PARTS LIST

1 Individual pixels
100 two-dimensional display
11 one-dimensional array of edge emissive pixels
12 substrate
13 circuitry
15 IC chip
2 display slice
21 position
22 control electrodes
23 anode or cathode
24 data-input electrode
25 IC chip
16 power electrode
27 pixel
3 two dimensional array of pixels
30 emissive face
31 pixel circuits
41 face edge
42 plane
43 line
44 connection structure
45 memory circuit
46 pixel-selection transistors tsel
47 memory circuit
48 second pixel selection transistor
49 first pixel selection transistor

What is claimed is:

1. A display device comprising:
a plurality of Y display slices, each display slice having electronic structures on or in the display slice, such electronic structures including a one-dimensional array of X adjacent pixels that emit light from a face edge of the display slice in response to electrical power, with the display slices being assembled in a layered arrangement with the face edges of the Y display slices each forming one layer of an emissive face;
a plurality of control electrodes;
a plurality of power electrodes;
a plurality of data electrodes; and
a connection structure on or in each display slice, each connection structure connecting at least (a) each of a plurality of groups of the corresponding display slice's pixels to a separate one of the control electrodes, (b) one or more of the power electrodes to at least one of the corresponding display slice's electronic structures, and (c) one or more of the data electrodes to at least one of the corresponding display slice's electronic structures.

2. The device of claim 1, wherein the electronic structures on or in each display slice comprise a first electronic structure having a first input connected to one of the power electrodes, a second input connected to one of the data electrodes, and a plurality of outputs, each output connected to a different pixel in one of the groups of pixels in the respective display slice.

3. The device of claim 2, wherein the first electronic structure is an integrated circuit.

4. The device of claim 2, wherein each output of the first electronic structure is connected to positionally-corresponding pixels in at least two of the groups of pixels in the respective display slice, and wherein no two outputs of the first electronic structure are connected to a same pixel in any of the groups of pixels.

5. The device of claim 2, wherein each output of each first electronic structure is connected to positionally-corresponding pixels in all of the groups of pixels in the respective display slice, and wherein no two outputs of the first electronic structure are connected to a same pixel in any of the groups of pixels.

6. The device of claim 2, further comprising timing circuitry connected to the plurality of control electrodes and the data electrodes and configured to cause the groups of pixels to emit radiation in sequence at a frame refresh cycle greater than 20 Hz.

7. The device of claim 1, wherein each display slice comprises a memory circuit connected at least to one of the respective display slice's pixels.

8. The device of claim 7, further comprising timing circuitry connected to the plurality of control electrodes and the data electrodes and configured to cause the groups of pixels to refresh data in their memory circuits in sequence at a frequency greater than 20 Hz.

9. The device of claim 7, wherein each memory circuit comprises two pixel-selection transistors, and wherein each memory circuit is connected via the respective pixel-selection transistors to one of the data electrodes.

10. The device of claim 9,
wherein each memory circuit comprises a first pixel-selection transistor and a second pixel-selection transistor,
wherein the plurality of control electrodes comprise a plurality of group-select electrodes and a plurality of column-select electrodes,
wherein the first pixel-selection transistors in the memory circuits for one of the groups of pixels in a display slice are controlled by a same group-select electrode, and
wherein the second pixel-selection transistors in the memory circuits for the one of the groups of pixels are controlled by different column-select electrodes.

11. The device of claim 10, comprising X columns of pixels in the emissive face, and the device further comprises timing circuitry connected to the plurality of group-select electrodes, the plurality of column-select electrodes, and the data electrodes and configured to cause the X columns of pixels to refresh data in their memory circuits in sequence at a frequency greater than 20 Hz.

12. The device of claim 7,
wherein each memory circuit comprises a pixel-selection transistor,
wherein each memory circuit is connected via the respective pixel-selection transistor to one of the data electrodes, and
wherein each display slice comprises a first electronic structure having a first input connected to one of the power electrodes, a second input connected to one of the data electrodes, and a plurality of outputs, each output connected to one of the pixel-selection transistors in one of the groups of pixels in the respective display slice.

13. The device of claim 10, wherein each display slice comprises C groups of G pixels, wherein C and G are positive integers, wherein C*G=X, and wherein a number of electrical interconnections P between display slices is greater than or equal to C+3 and less than or equal to C+15.

14. The device of claim 13, wherein P also is a total number of connections to all of the display slices, collectively.

15. The device of claim 13, wherein X is 3840.

16. The device of claim 13, wherein P is less than or equal to C+14, and X is 1920.

17. The device of claim 2, wherein each display slice comprises C groups of G pixels, wherein C and G are positive integers, wherein C*G=X, and wherein a number of input connections N to the first electronic structure is greater than or equal to G+3 and less than or equal to G+15.

18. The device of claim 17, wherein X is 3840.

19. The device of claim 17, wherein N is less than or equal to G+14, and X is 1920.

20. The device of claim 17, wherein X is 1920, G is 30, C is 64, N is inclusively between 33 and 44, and a number of interconnections P between display slices is inclusively between 67 and 77.

21. The device of claim 10, wherein each display slice comprises C groups of G pixels, wherein C and G are positive integers, wherein C*G=X, and wherein a number of connections P interconnecting display slices is approximately G+C+2.

22. The device of claim 1, wherein each display slice comprises a plurality of control electrodes connected to control electrodes in an adjacent display slice, wherein connections between control electrodes through all of the display slices form or substantially form a line perpendicular or substantially perpendicular to a plane of the display slice.

23. The device of claim 1, wherein each display slice includes only red pixels, only blue pixels, or only green pixels.

24. The device of claim 1, further comprising an anisotropic conductive adhesive between each display slice.

25. The device of claim 1, wherein at least one of the electronic structures includes sensing capabilities that detect the proximity of an object.

26. A display device comprising:
a plurality of Y display slices, each display slice having electronic structures on or in the display slice, such electronic structures including a one-dimensional array of X adjacent pixels that emit light from a face edge of the display slice in response to electrical power, with the display slices being assembled in a layered arrangement with the face edges of the Y display slices each forming one layer of an emissive face; and
circuitry on or in each display slice, the circuitry including a plurality of electronic structures, a plurality of power electrodes, a plurality of data electrodes, a pixel selection electrode, and a connection structure, the connection structure connecting the circuitry to the pixels on the respective display slice,
wherein the circuitry for each display slice is behind the respective one-dimensional edge-emissive array with respect to the emissive face.

27. The device of claim 1, wherein each of the display slices is formed of a flexible material capable of being formed into a roll.

28. Display device components comprising:
a plurality of display slices formed side-by-side as a roll of flexible material;
a one-dimensional edge-emissive array of adjacent pixels formed with each display slice;
a plurality of control electrodes formed with each display slice;
a plurality of power electrodes formed with each display slice;
a plurality of data electrodes formed with each display slice; and
a connection structure formed with each display slice, each connection structure connecting at least (a) each of a plurality of groups of the corresponding display slice's pixels to a separate one of the control electrodes, (b) one or more of the power electrodes to at least one of the corresponding display slice's electronic structures, and (c) one or more of the data electrodes to at least one of the corresponding display slice's electronic structures.

29. A method of forming a display device, the method comprising:
forming side-by-side groups of display slices as a roll of flexible material, each display slice including a one-dimensional edge-emissive array of adjacent pixels, a plurality of control electrodes, a plurality of power electrodes, a plurality of data electrodes, and a connection structure, each connection structure connecting at least (a) each of a plurality of groups of the corresponding display slice's pixels to a separate one of the control electrodes, (b) one or more of the power electrodes to at least one of the corresponding display slice's electronic structures, and (c) one or more of the data electrodes to at least one of the corresponding display slice's electronic structures;
separating display slices from each of the side-by-side groups of display slices; and
joining the separated display slices in a layered manner that forms connections at least between control electrodes in each display slice.

30. The method of claim 29, wherein the joining occurs at least by an anistoropic conductive paste or film.

31. The method of claim 29, wherein the connections between control electrodes in each display slice form or substantially form a line perpendicular or substantially perpendicular to a plane of each layered display slice.

32. The method of claim 31, wherein each side-by-side group of display slices includes a one-dimensional edge-emissive array of pixels for a single color channel different than the other side-by-side groups of display slices.

33. The method of claim 32, wherein the joining joins separated display slices for different color channels in a repeating manner.
